(19) United States
(12) Patent Application Publication
(10) Pub. No.: US 2019/0095098 A1
(43) Pub. Date: Mar. 28, 2019

(54) SEMICONDUCTOR MEMORY DEVICE RELATING TO THE DETERMINATION OF A MAJORITY OR MINORITY LEVEL AND SEMICONDUCTOR SYSTEM INCLUDING THE SAME

(71) Applicant: SK hynix Inc., Icheon-si Gyeonggi-do (KR)

(72) Inventor: Jae Woong YUN, Seoul (KR)

(73) Assignee: SK hynix Inc., Icheon-si Gyeonggi-do (KR)

(21) Appl. No.: 15/886,045

(22) Filed: Feb. 1, 2018

(30) Foreign Application Priority Data
Sep. 28, 2017 (KR) 10-2017-0126124

(51) Int. Cl. G06F 3/06; G06F 11/10; G11C 29/52

(52) U.S. Cl. CPC G06F 3/061; G06F 3/0644; G11C 29/52; G06F 3/0673; G06F 11/1068; G06F 3/0659

(57) ABSTRACT

A semiconductor memory device may include a data-determining circuit and a memory cell array. The data-determining circuit may receive data to determine a majority level of data among the received data. The data-determining circuit may provide data bus inversion information to invert data of an address including a minority level of data. The memory cell array may store the data bus inversion information through a redundant bit line.

### CROSS-REFERENCES TO RELATED APPLICATION

The present application claims priority under 35 U.S.C. § 119(a) to Korean application number 10-2017-0126124, filed on Sep. 28, 2017, in the Korean Intellectual Property Office, which is incorporated herein by reference in its entirety.

### BACKGROUND

### 1. Technical Field

Various embodiments generally relate to a semiconductor memory device and a semiconductor system including the same, more particularly a semiconductor memory device relating to the determination of a majority or minority level, and a semiconductor system including the semiconductor memory device.

### 2. Related Art

A reading operation and a writing operation in a semiconductor system may be performed by exchanging data including bits between a controller and a semiconductor device. In the reading operation, the data in the semiconductor device may be outputted. The outputted data may then be transmitted to the controller. In the writing operation, the data applied to the controller may be stored in a memory region of the semiconductor device. A data masking (DM) operation may be performed to store desired bits among the data applied to the controller in the memory region. That is, the semiconductor device may store the desired bits or block inputs of the data among the data applied to controller.

Generations of a simultaneous switching noise (SSN) and an inter symbol interface (ISI) may be increased proportional to increasing of the bits having phases, which may be changed compared to a previous point, among the bits of the data transmitted in a semiconductor system. Thus, when the bits having the changed phases compared to the previous point among the bits of the data transmitted in the semiconductor system are increased, a data bus inversion (DBI) may be performed to invert and transmit the data, thereby decreasing the generations of the SSN and the ISI.

### SUMMARY

In an embodiment, a semiconductor memory device may include a data-determining circuit and a memory cell array. The data-determining circuit may receive data to determine a majority level of data among the received data. The data-determining circuit may provide data bus inversion information to invert data of an address including a minority level of data. The storing circuit for example, a memory cell array may store the data bus inversion information through a redundant bit line.

In an embodiment, a semiconductor memory device may include a global input and output (input/output) (GIO) driving circuit, a data-determining circuit, a local input/output (LIO) driving circuit and a memory cell array. The GIO driving circuit may receive data through a GIO line. The data-determining circuit may determine majority and minority levels of the data to provide the GIO driving circuit with data bus inversion information for inverting a minority level of data among the data. The LIO driving circuit may receive and drive the data outputted from the GIO driving circuit and the data bus inversion information. The memory cell array may include a plurality of memory cells and a redundant memory cell. The memory cells may store the data and the data bus inversion information outputted from the LIO driving circuit.

In an embodiment, a semiconductor system may include a controller and a semiconductor memory device. The controller may output a write command and a read command. The controller may input/output data. The semiconductor memory device may include a data-determining circuit and a redundant memory cell. The data-determining circuit may receive data to determine a majority level of data among the received data. The data-determining circuit may provide data bus inversion information to invert data of an address including a minority level of data. The redundant memory cell may store the data bus inversion information.

### BRIEF DESCRIPTION OF THE DRAWINGS

FIG. 1 is a block diagram illustrating a semiconductor system in accordance with an example of an embodiments.

FIG. 2 is a block diagram illustrating writing operations of writing a semiconductor memory device in accordance with an example of an embodiment.

FIG. 3 is a block diagram illustrating a data-determining circuit in accordance with an example of an embodiment.

FIG. 4 is a block diagram illustrating reading operations of a semiconductor memory device in accordance with an example of an embodiment.

FIGS. 5 and 6 are flow charts illustrating operations for driving a semiconductor memory device in accordance with an example of the embodiments.

FIG. 7 is a block diagram illustrating a semiconductor system in accordance with an example of an embodiment.

### DETAILED DESCRIPTION

Hereinafter, examples of embodiments will be described below with reference to the accompanying drawings through various examples. Like reference numerals and characters refer to like elements throughout.

Examples of the embodiments may provide a semiconductor memory device that may be capable of reducing current dissipation.

Examples of the embodiments may provide a semiconductor system including the above-mentioned semiconductor memory device.

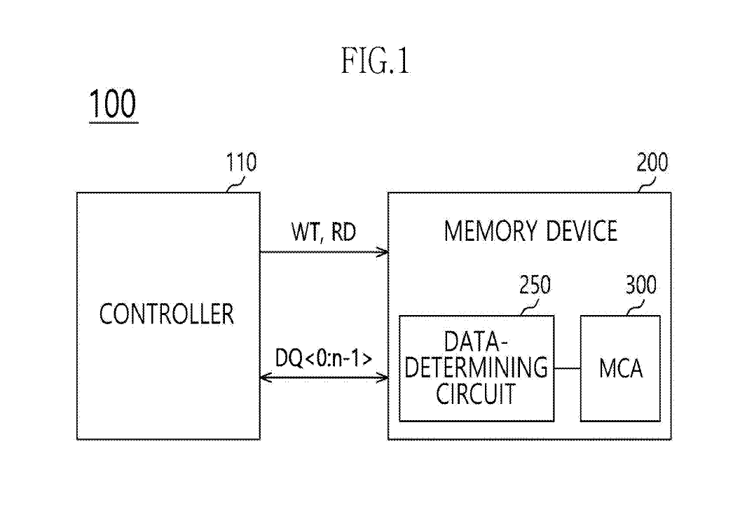

FIG. 1 is a block diagram illustrating a semiconductor system in accordance with an example of an embodiment.

Referring to FIG. 1, in an example of an embodiment, a semiconductor system 100 may include a controller 110 and a memory device 200.

The controller 110 may provide the memory device 200 with commands such as a write command WT, a read command RD, etc. The controller 110 may provide the memory device 200 with data DQ<0:n−1> or receive the data DQ<0:n−1> from the memory device 200 in accordance with the commands.

The memory device 200 may receive the data DQ<0:n−1> from the controller 110. The memory device 200 may include a data-determining circuit 250 and a memory cell array MCA. The data-determining circuit 250 may determine a majority level of the data DQ<0:n−1> to process the data DQ<0:n−1>. For example, the data-determining circuit 250 may determine the majority of bits within the data DQ<0:n−1> that gave the same voltage level, logic level, predetermined voltage level, etc. For example, when a majority of the bits included in the data DQ<0:n−1> have a high level (i.e., logic high level, a predetermined voltage level, etc.), the data-determining circuit 250 may determine the majority level to be high and a minority level to be low. For example, when a majority of the bits included in the data DQ<0:n−1> have a low level (i.e., logic low level, a predetermined voltage level, etc.), the data-determining circuit 250 may determine the majority level to be low and the minority level to be high.

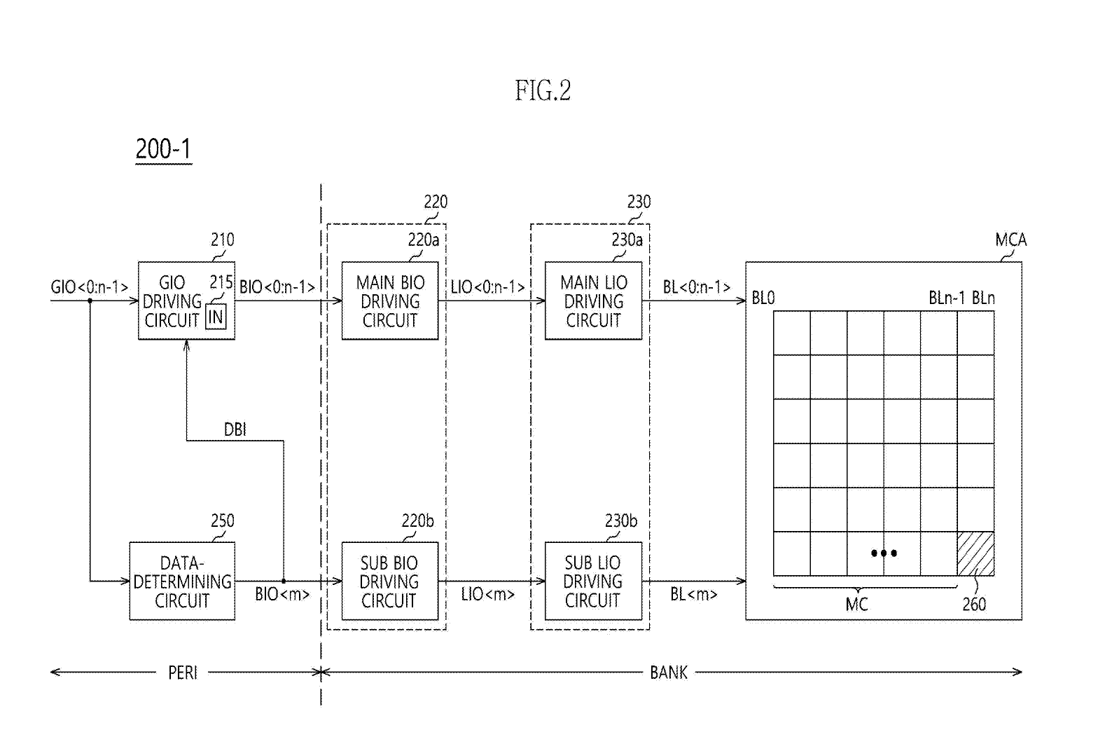

FIG. 2 is a block diagram illustrating writing operations of writing a semiconductor memory device in accordance with an example of an embodiment.

Referring to FIG. 2, the memory device 200 may be, for example, a semiconductor memory device 200_1. The semiconductor memory device 200_1 may include a global input/output (GIO) driving circuit 210, a bank input/output (BIO) driving circuit 220, a local input/output (LIO) driving circuit 230, the data-determining circuit 250 and the memory cell array MCA 300. In an embodiment, for example, the global input/output (GIO) driving circuit 210, the bank input/output (BIO) driving circuit 220, the local input/output (LIO) driving circuit 230, and the data-determining circuit 250 may be implemented with software, hardware, or any combination thereof. Further, the global input/output (GIO) driving circuit 210, the bank input/output (BIO) driving circuit 220, the local input/output (LIO) driving circuit 230 may correspond to a data driving circuit.

When the write command WT is inputted from the controller 110, the data DQ<0:n−1> provided from the controller 110 may be transmitted through a GIO line GIO<0:n−1>.

The GIO line GIO<0:n−1> may be coupled to the GIO driving circuit 210 as a data driving circuit and The data-determining circuit 250.

The data-determining circuit 250 may receive the data DQ<0:n−1> from the GIO line GIO<0:n−1>. The data-determining circuit 250 may output signals for determining and converting the levels of the bits included in the data DQ<0:n−1>.

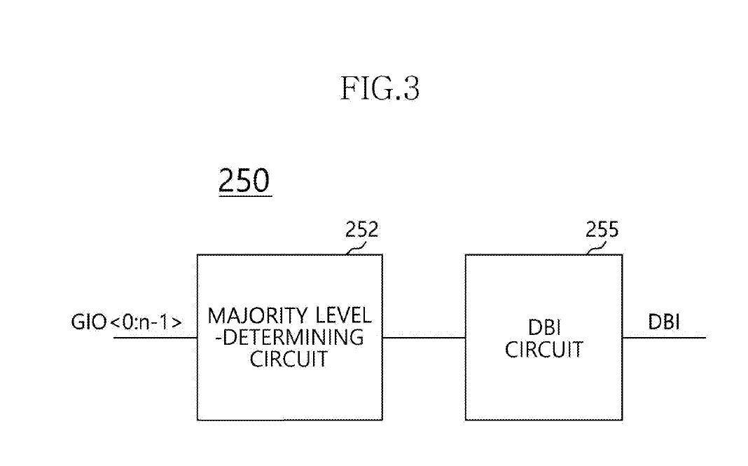

FIG. 3 is a block diagram illustrating a data-determining circuit in accordance with an example of an embodiment.

Referring to FIG. 3, the data-determining circuit 250 may include a majority level-determining circuit 252 and a data bus inversion (DBI) circuit 255.

The majority level-determining circuit 252 may receive the logic or voltage levels of the bits included in the data DQ<0:n−1> form the GIO line GIO<0:n−1>. The majority level-determining circuit 252 may determine the majority level of the data DQ<0:n−1>. For example, the majority level-determining circuit 252 may be configured to determine the majority of bits within the received data DQ<0:n−1> that have the same logic level. For example, when a majority of the bits included in the data DQ<0:n−1> have a high level (i.e., logic high level, voltage level, or predetermined voltage level, etc.), the majority level-determining circuit 252 may determine the majority level to be high and a minority level to be low. For example, when a majority of the bits included in the data DQ<0:n−1> have a low level (i.e., logic low level, voltage level, or predetermined voltage level, etc.), the majority level-determining circuit 252 may determine the majority level to be low and the minority level to be high.

The DBI circuit 255 may output a DBI signal to an address corresponding to the bits of data for the minority level of the data.

Referring to FIG. 2, the GIO driving circuit 210 may be coupled with the GIO line GIO<0:n−1> to receive the data DQ<0:n−1> from the GIO line GIO<0:n−1>. The GIO driving circuit 210 may further include a data-processing circuit 215. The data-processing circuit 215 may receive the DBI signal provided from the data-determining circuit 250 to convert the minority level of the data to the majority level of the data. The data-processing circuit 215 may include an inverting circuit ‘IN’ driven in response to the DBI signal DBI. For example, the inverting circuit ‘IN’ may selectively perform an inverting operation according to the DBI signal, as like a 3 state inverter. If the DBI signal is enabled, the inverting circuit ‘IN’ of the GIO driving circuit 210 may invert the minority level of the data to the majority level of the data. Thus, the GIO driving circuit 210 may output the data DQ<0:n−1> having the majority level.

The GIO driving circuit 210 may drive (transmit) the data DQ<0:n−1> having the majority level to a bank input/output (BIO) line BIO<0:n−1>. The DBI signal is transmitted to the sub BIO driving circuit 220b through the BIO<m>. BIO<m> and LIO<m> are just an m th interconnection layer.

The BIO driving circuit 220 may include a main BIO driving circuit 220a and a sub BIO driving circuit 220b.

The main BIO driving circuit 220a may receive the data output from the GIO driving circuit 210 from the BIO line BIO<0:n−1>. The main BIO driving circuit 220a may drive the data to output the driven data to a LIO line LIO<0:n−1>.

The sub BIO driving circuit 220b may receive the DBI signal as the data bus inversion information by the addresses outputted from the data-determining circuit 250 through a redundant BIO line BIO<m>. The sub BIO driving circuit 220b may buffer the DBI information received through the redundant BIO line BIO<m> to output the buffered DBI information to a redundant LIO line LIO<m>.

The LIO driving circuit 230 may include a main LIO driving circuit 230a and a sub LIO driving circuit 230b.

The main LIO driving circuit 230a may receive the data from the LIO line LIO<0:n−1>. The main LIO driving circuit 230a may drive the data to output the driven data to a bit line BL<0:n−1> in the memory cell array MCA.

The sub LIO driving circuit 230b may receive the DBI information from a redundant LIO line LIO<m>. The sub LIO driving circuit 230b may buffer the buffered DBI information which inputted from the redundant LIO line LIO<m> to a redundant bit line BL BL<m>.

The data in the bit lines BL<0:n−1> may be written in a corresponding memory cell MC. A reference numeral 260 may represent a redundant (extra) memory cell configured to store the DBI information provided from the redundant bit line BL<m>, as a storing circuit. The redundant memory cell 260 may be at least one.

The semiconductor memory device 200_1 may include a peripheral region PERI and a bank region BANK. The GIO driving circuit 210 and the data-determining circuit 250 may be arranged in the peripheral region PERI. The BIO driving circuit 220, the LIO driving circuit 230 and the memory cell array 300 may be arranged in the bank region BANK.

The BIO line BIO<0:n−1>, the redundant BIO line BIO<m>, and the BIO driving circuit 220 may function to stabilize the data DQ<0:n−1> from the GIO line GIO<0:n−1>. Alternatively, the semiconductor memory device 200_1 may not include the BIO line BIO<0:n−1>, the redundant BIO line BIO<m>, and the BIO driving circuit 220. In this case, when the BIO line BIO<0:n−1>, the redundant BIO line BIO<m>, and the BIO driving circuit 220 are not included, the GIO driving circuit 210 and the LIO driving circuit 230 may be coupled with each other through the LIO line LIO<0:n−1> and the redundant LIO line LIO<m>.

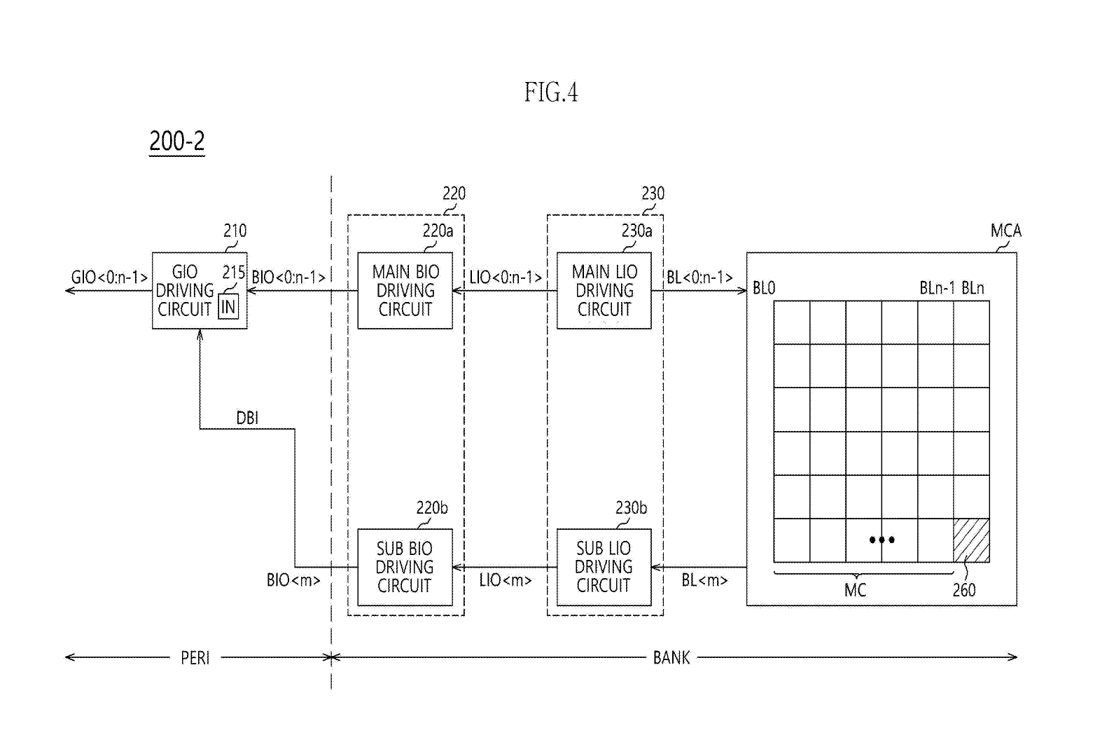

FIG. 4 is a block diagram illustrating reading operations of a semiconductor memory device in accordance with an example of an embodiment.

Referring to FIG. 4, the memory device 200 may be, for example, a semiconductor memory device 200_2. In an embodiment, for example, the semiconductor memory device 200_2 may include the same elements as the semiconductor memory device 200_1. In an embodiment, for example, the semiconductor memory device 200_2 may include the same elements as the semiconductor memory device 200_1 but not utilize the data-determining circuit 250 with a read command. In an embodiment, for example, the semiconductor memory device 200_2 may include the same elements as the semiconductor memory device 200_1 but for the data-determining circuit 250. As such, when the read command of the controller 110 is inputted, the data information in the memory cells MC may be read through the bit line BL<0:n−1>. The read data information may be transmitted to the main LIO driving circuit 230a. The data bus inversion information in the redundant memory cell 260 may be transmitted to the sub LIO driving circuit 230b through the redundant bit line BL<m>.

The read data and the data bus inversion information may be driven by the main LIO driving circuit 230a and the sub LIO driving circuit 230b. The driven read data and the driven data bus inversion information may be transmitted to the LIO line LIO<0:n−1> and the redundant LIO line LIO<m>, respectively.

The read data and the inversion information in the LIO line LIO<0:n−1> and the redundant LIO line LIO<m>, respectively, may be transmitted to the main BIO driving circuit 220a and the sub BIO driving circuit 220b, respectively. The main BIO driving circuit 220a and the sub BIO driving circuit 220b may, respectively, drive (buffer and transmit) the read data and the inversion information. The driven read data and the driven inversion information may be outputted to the BIO line BIO<0:n−1> and the redundant BIO line BIO<m>, respectively.

The GIO driving circuit 210 may receive the read data through the BIO line BIO<0:n−1> and the data bus inversion information through the redundant BIO line BIO<m>.

The data-processing circuit 215 of the GIO driving circuit 210 may invert the data, from the BIO line BIO<0:n−1>, of the corresponding address in response to the data bus inversion information signal, received through the redundant BIO line BIO<m>, to restore the data to the original data.

The GIO driving circuit 210 may drive (buffer and transmit) the majority of the bits of the data corresponding to majority level and the restored data corresponding to the minority level. The driven majority and minority data may be outputted to the GIO line GIO<0:n−1>. The outputted data DQ<0:n−1> may be provided to the controller 110.

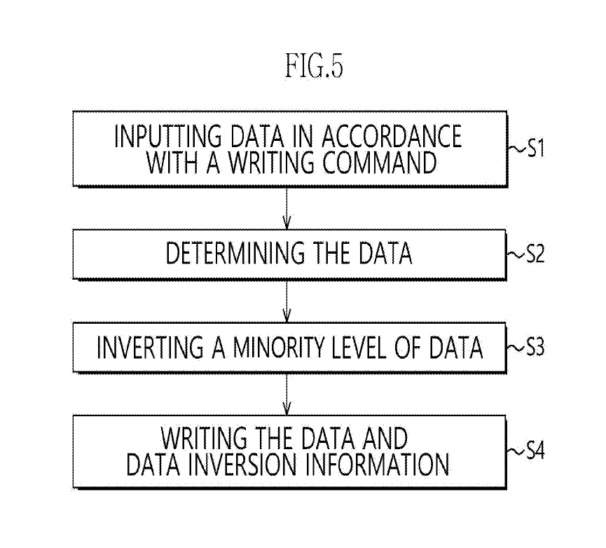

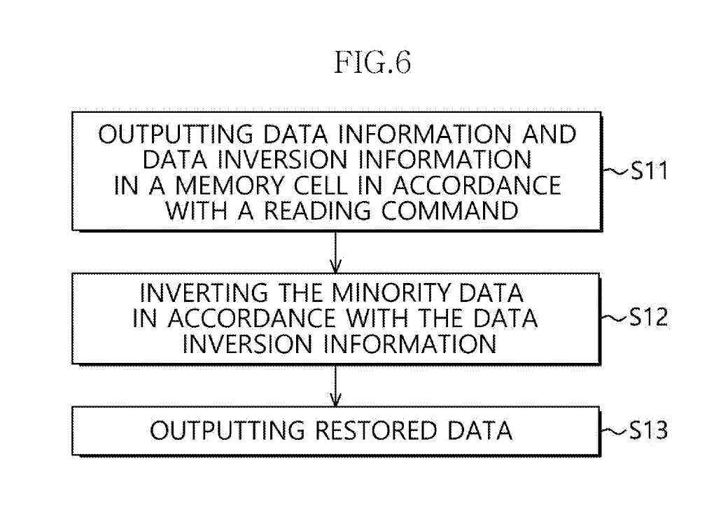

FIGS. 5 and 6 are flow charts illustrating operations for driving a semiconductor memory device in accordance with an example of the embodiments.

Referring to FIG. 5, in step S1, the data DQ<0:n−1> may be inputted through the GIO line GIO<0:n−1> based on the write command.

In step S2, the data-determining circuit 250 may determine the majority of bits within the received data that have a same logic level from among the inputted data DQ<0:n−1>.

In step S3, the inversion-processing command may be provided to the minority level of the bits of the address to invert the bits determined as the minority level of the data.

In step S4, the majority level of the data and the minority level of the data may be written in the memory cell. Simultaneously, or substantially simultaneously, the data bus inversion information of the address may be written in the redundancy memory cell.

Referring to FIG. 6, in step S11, the data information in the memory cell and the data bus inversion information in the redundant memory cell may be outputted to the GIO driving circuit 210 through the data output lines BL, LIO, and BIO and the data-driving circuit 220 and 230 in response to the read command.

In step S12, the GIO driving circuit 210 may invert the minority level of the data in accordance with the data bus inversion information.

In step S13, the GIO driving circuit 210 may output the restored data to the controller 110.

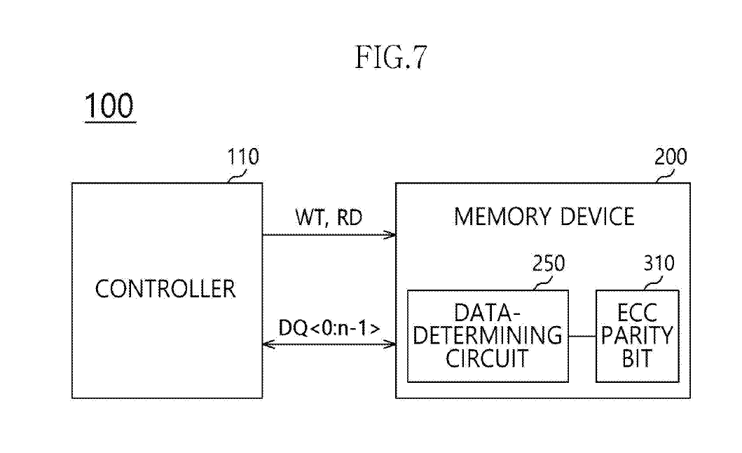

In examples of the embodiments, the structure configured to store the data bus inversion information in the redundant memory cell 260 may be illustrated. Alternatively, as illustrated in FIG. 7, the data bus inversion information may be stored in an error correction code (ECC) parity bit 310 of the memory device 200.

The semiconductor memory device may realize by a DRAM device, a PCRAM device, ReRAM device, etc., or any combination thereof.

The above embodiments of the present disclosure are illustrative and not limitative. Various alternatives and equivalents are possible. The examples of the embodiments are not limited by the embodiments described herein. Nor is the present disclosure limited to any specific type of semiconductor memory device or semiconductor system. Other additions, subtractions, or modifications are obvious in view of the present disclosure and are intended to fall within the scope of the appended claims.

What is claimed is:

1. A semiconductor memory device comprising:
a data-determining circuit configured to receive data and determine a majority level of data among the received data, and provide data bus inversion information for inverting data of an address having a minority level of data; and
a storing circuit configured to store the data bus inversion information through a redundant data line.

2. The semiconductor memory device of claim 1, wherein to determine the majority level of data among the received data, the data-determining circuit is configured to determine the majority of bits within the received data that have a same logic level.

3. The semiconductor memory device of claim 1, wherein the storing circuit includes a memory cell array,
wherein the memory cell array comprises:
a plurality of memory cells configured to store the majority level of the data and majority level of data which generated by inverting the minority level of the data; and
the memory cell array including an redundant memory cell configured to store the data bus inversion information.

4. The semiconductor memory device of claim 1,
wherein the memory cell array comprises:
a plurality of memory cells configured to store the majority level of the data and majority level of data which generated by inverting the minority level of the data; and
an error correction code (ECC) parity cell configured to store the data bus inversion information.

5. The semiconductor memory device of claim 1, further comprising a data-driving circuit configured to receive the data,
wherein the data-driving circuit is configured to drive and output the majority level of the data and the data-driving circuit further comprises a data-processing circuit configured to invert the minority level of the data.

6. The semiconductor memory device of claim 5, wherein the data-driving circuit includes a global input/output (GIO) driving circuit.

7. A semiconductor memory device comprising:
a global input and output (input/output) (GIO) driving circuit configured to receive data through a GIO line;
a data-determining circuit configured to determine majority and minority levels of the data inputted through the GIO line and to provide the GIO driving circuit with data bus inversion information for inverting a minority level of data;
a local input/output (LIO) driving circuit configured to receive and drive the data and the data bus inversion information outputted from the GIO driving circuit; and
a memory cell array including a plurality of memory cells and a redundant memory cell configured to store the data and the data bus inversion information from the LIO driving circuit.

8. The semiconductor memory device of claim 7, wherein the GIO driving circuit inverts the minority level of the data in response to the data bus inversion information outputted from the data-determining circuit in a writing operation, and the GIO driving circuit restores the minority level of the data in accordance with the data bus inversion information in a reading operation.

9. The semiconductor memory device of claim 7, wherein the LIO driving circuit comprises:
a main LIO driving circuit configured to drive the data; and
a sub LIO driving circuit configured to buffer the data bus inversion information.

10. The semiconductor memory device of claim 7, further comprising a bank input/output (BIO) driving circuit configured to stabilize the data between the GIO driving circuit and the LIO driving circuit.

11. A semiconductor system comprising:
a controller configured to output a write command and a read command for inputting and outputting data; and
a semiconductor memory device including data-determining circuit configured to receive the data and determine a majority level of data among the received data, and provide data bus inversion information for inverting data of an address having a minority level of data, and a redundant memory cell configured to store the data bus inversion information.

12. The semiconductor system of claim 11, wherein the semiconductor memory device further comprises a memory cell array,
wherein the memory cell array comprises:
a plurality of memory cells configured to store the minority level of the data; and
the redundant memory cell configured to store the data bus inversion information.

13. The semiconductor system of claim 12, wherein the semiconductor memory device further comprises a global input and output (GIO) data-driving circuit configured to receive the data, and the GIO data-driving circuit comprises a data-processing circuit configured to coincide the minority level of the data with the majority level of the data in accordance with the data bus inversion information based on the write command and to restore the minority level of the data in accordance with the data bus inversion information based on the read command.
